(19) United States
(12) Patent Application Publication
(10) Pub. No.: US 2006/0232940 A1
(43) Pub. Date: Oct. 19, 2006

(54) Method for mounting a switching module, switching module and pressure pad

(75) Inventors: Karl Smirra, Wasserburg (DE); Gunter Scheid, Nittendorf (DE); Georg Fischer, Reifenthal (DE); Arnoud Smit, Regensburg (DE)

Correspondence Address: LERNER GREENBERG STEMER LLP, P O BOX 2480, HOLLYWOOD, FL, 33022-2480, US

(73) Assignee: Siemens Aktiengesellschaft

(21) Appl. No.: 10/531,250

(22) PCT Filed: Sep. 9, 2003
(86) PCT No.: PCT/DE03/02991

§ 371 Date: Feb. 13, 2006

(30) Foreign Application Priority Data
Oct. 14, 2002 (DE) 102 47 773.6

(51) Int. Cl. H05K 7/20

(52) U.S. Cl. 361/707

(57) ABSTRACT

The invention relates to a method for producing a housing, wherein the base body of the housing (10) is initially separated from a hollow profile and a printed circuit board (1) is subsequently inserted into the base body of the housing (10). The base body of the housing (10) is then closed laterally with the aid of covering elements (6).

The invention relates to a method for mounting a switching module, in which a circuit support is inserted into a basic housing element and the basic housing element is closed with the aid of cover elements.

The invention also relates to a pressure strip and a switching module with an electronic component.

Electronic components have to be protected from environments that are subject to dirt and vibration. Therefore special housings are developed to accommodate printed circuit boards for electronic transmission controllers, the dimensions and structure of said housings being tailored to the printed circuit boards used in each instance. Known housings only bear a very slight mechanical similarity to each other. Also a specific, new set of tools is required to produce base plates, covers, plug connectors and further fixing elements for each type of housing.

However there is a demand for housings that are economical to produce and simple to mount and are suitable for accommodating an electronic control system arranged outside the transmission. These housings may be sealed or unsealed. The structure of the device and the mounting process should be achieved with the smallest possible number of components and work and process steps. It should also be possible to tailor the housings easily to different printed circuit board dimensions, without leaving unused empty space inside the housing.

Based on this prior art, the object of the invention is therefore to create a simple and economical method for mounting a switching module. It is also the object of the invention to provide a suitable semi-finished product to implement the method.

These objects are achieved by the method, the switching module and the pressure strip with the features set out in the independent claims. Advantageous embodiments and developments are set out in the dependent claims.

To produce a housing, the basic housing element is preferably produced by separating a hollow profile and closing the openings on the transverse sides of the basic housing elements with the cover elements.

As the basic housing element is produced by separating a hollow profile, the length of the basic housing element can be varied to an almost infinite degree. It is therefore possible to produce basic housing elements of different lengths from one hollow profile, which can be fitted with circuit supports of different lengths. The length of the basic housing element can particularly be selected such that there is no empty volume within the housing.

The hollow profile is preferably extrusion molded. This allows the sectional profile to be configured in a simple fashion such that a circuit support can be fixed inside the housing without further fixing means. It is thus possible for example to provide recesses extending along the longitudinal axis of the hollow profile, into which self-tapping screws can be screwed to fix the cover elements. Also bearing surfaces can be provided for the circuit support in the sectional profile, which are arranged such that a circuit support with components fitted on both sides can be inserted into the basic housing element.

The circuit support is preferably inserted into the basic housing element such that the flat sides of the circuit support face walls of the basic housing element. A longitudinally extended pressure strip is inserted into the space between the basic housing element and the circuit support and is in contact with both the basic housing element and the circuit support. The pressure generated by the pressure strip causes the circuit support to be pressed against the basic housing element and thus to be retained in the basic housing element.

This solution offers the advantage that the pressure strip can be inserted in a simple fashion through the openings, through which the circuit support is also inserted into the basic housing element. Therefore no additional openings are required in the basic housing element to fix the circuit support in the basic housing element. As a pressure strip is used to hold the circuit support down, there is no risk of the holder coming loose when subject to vibration. The holder, which uses the pressure strip inserted between the basic housing element and the circuit support, is therefore simple to mount and ensures secure fixing of the circuit support.

In a preferred embodiment the pressure strip is configured as a coil. When the coiled spring contracts, a force is transmitted, as a result of which the retaining force acting on the circuit support can be increased.

In a particularly preferred embodiment the pressure strip is a coiled tension spring, which contracts in the space between the circuit support and a wall of the basic housing element. Such a pressure strip is particularly well protected against seizing, as seizing points are eased by the tensile force of the spring.

In a further preferred embodiment the pressure strip has lock rings arranged one behind the other, which are deformed when the circuit support is mounted such that they mediate a spring force between the walls of the basic housing element and the circuit support.

To secure the printed circuit board in the basic housing element in a further embodiment a cover element is provided with a strut, which extends into the inside of the basic housing element, when said cover element is attached to the transverse side of the basic housing element. Guide grooves can be provided to guide the strut inside the basic housing element, said grooves preferably being of an encapsulated design, to prevent the shearing off of electronic components on the printed circuit board when the strut is inserted. Finally in order to hold the printed circuit board in the basic housing element, spring elements are configured along the struts, which press the printed circuit board onto a bearing surface. In a preferred embodiment these spring elements are made of a material with good heat-conducting properties, in particular a metal, e.g. a copper-beryllium alloy, so that heat can be dissipated from the printed circuit board to the base element via the spring elements.

In a modified embodiment the cover elements, which close opposite openings, are configured as complementary, in that one of the cover elements is provided with a strut, which engages positively in a recess in the opposite cover element. This can be achieved using a catch, hook or tooth type mechanism.

In a further preferred embodiment a cover element is provided with contact means, for example a bush or a plug connector. The contact means are preferably fixed to the printed circuit board before the printed circuit board is inserted into the basic housing element. Then during insertion into the basic housing element the printed circuit board guides the cover element so that it is held in position, for example during a screw tightening operation. When the cover element has been fixed to the basic housing element, the printed circuit board, which is fixed to the cover element by way of the contact means, is held securely in the basic housing element.

To dissipate the heat generated by the electronic components, cooling fins extending along the longitudinal axis can be configured on the outside of the basic housing element. It is also expedient in some instances to provide cooling fins on the cover elements, by means of which waste heat can be discharged to the ambient air.

The invention is described below using examples with reference to the accompanying drawing, in which:

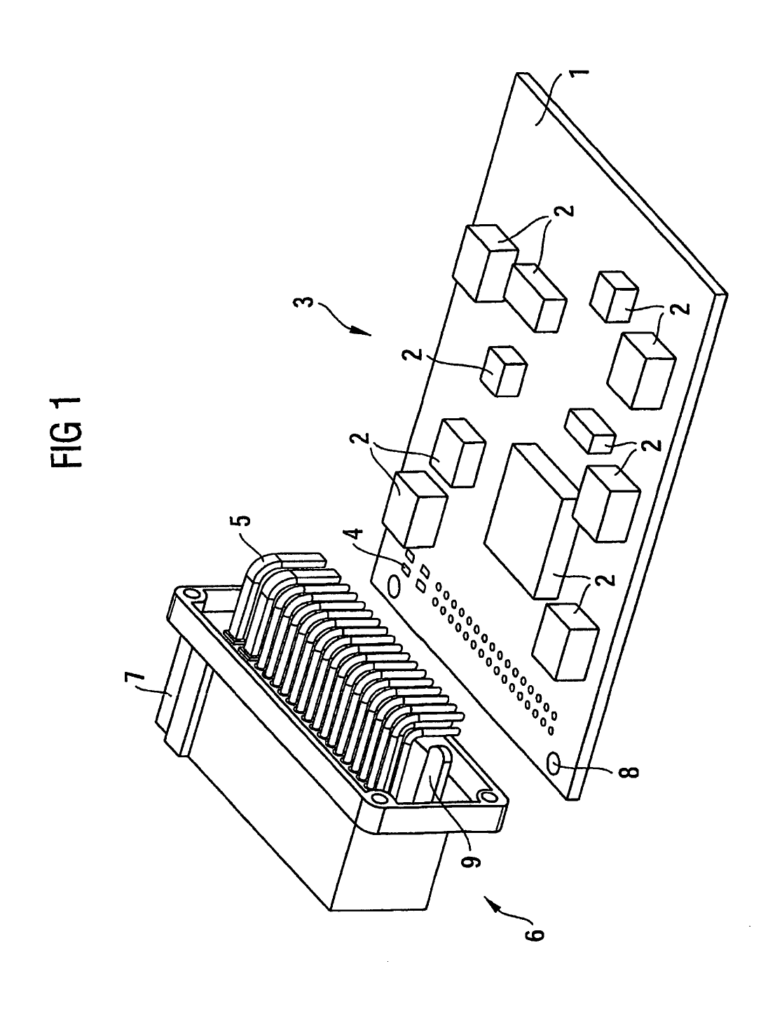

FIG. 1 shows a perspective view of a cover element provided with a plug connector, which can be fixed to a printed circuit board;

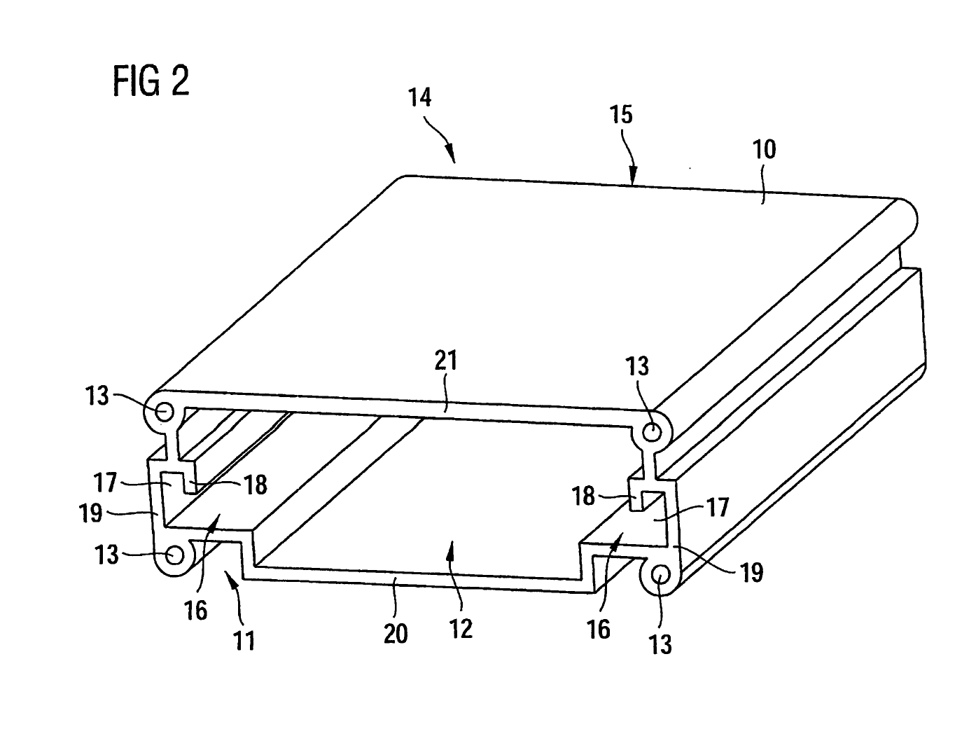

FIG. 2 shows a perspective view of a hollow element produced from an extrusion molded hollow profile;

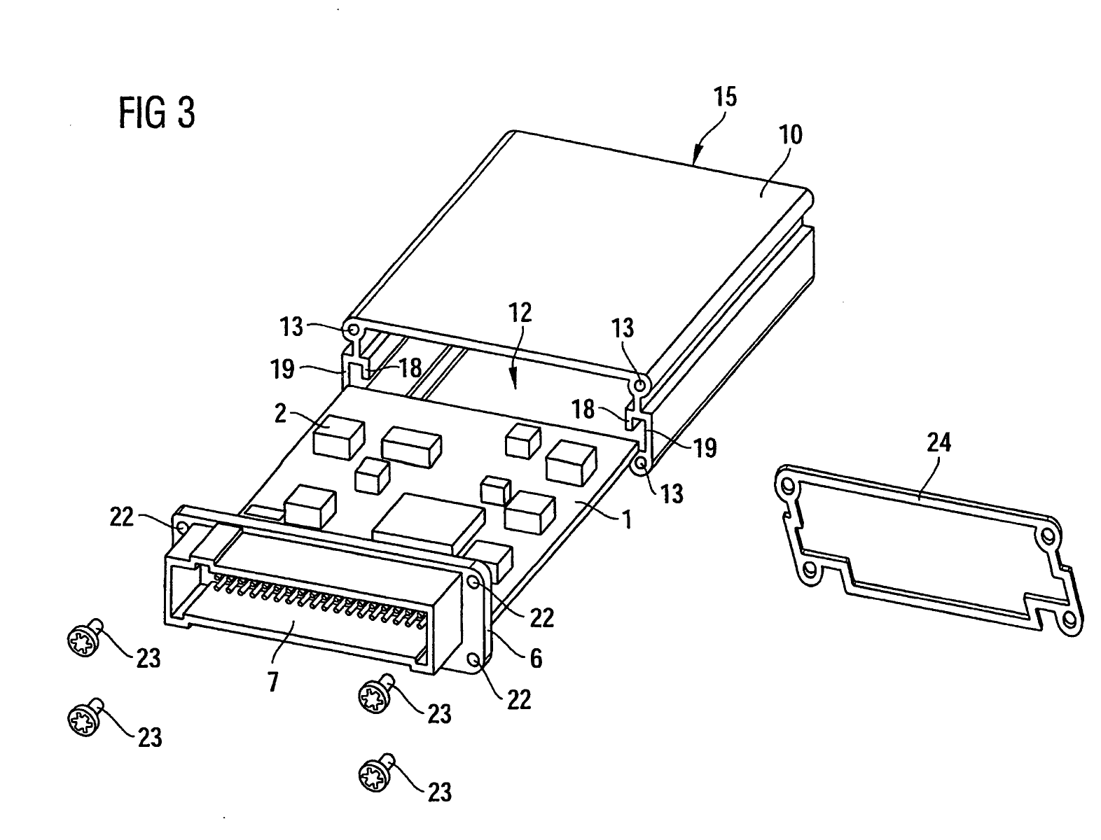

FIG. 3 shows a perspective view of a fixing process, in which the printed circuit board and the cover element attached thereto are inserted into the hollow element from FIG. 2;

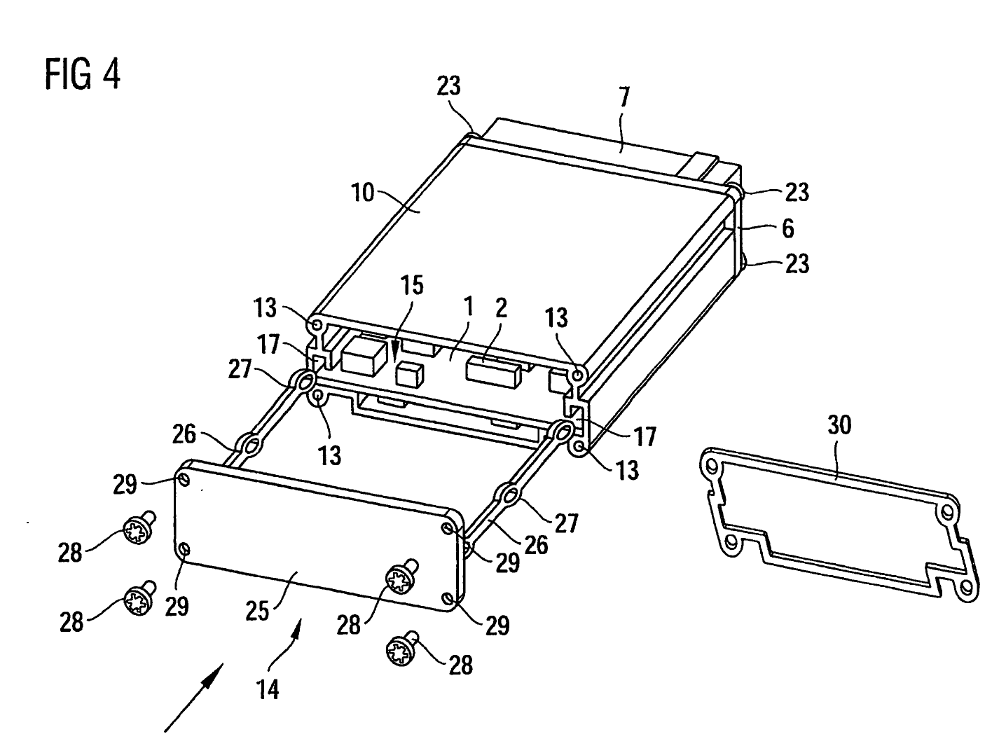

FIG. 4 shows a perspective view of the fixing process for the opposite cover element on the hollow element from FIGS. 2 and 3;

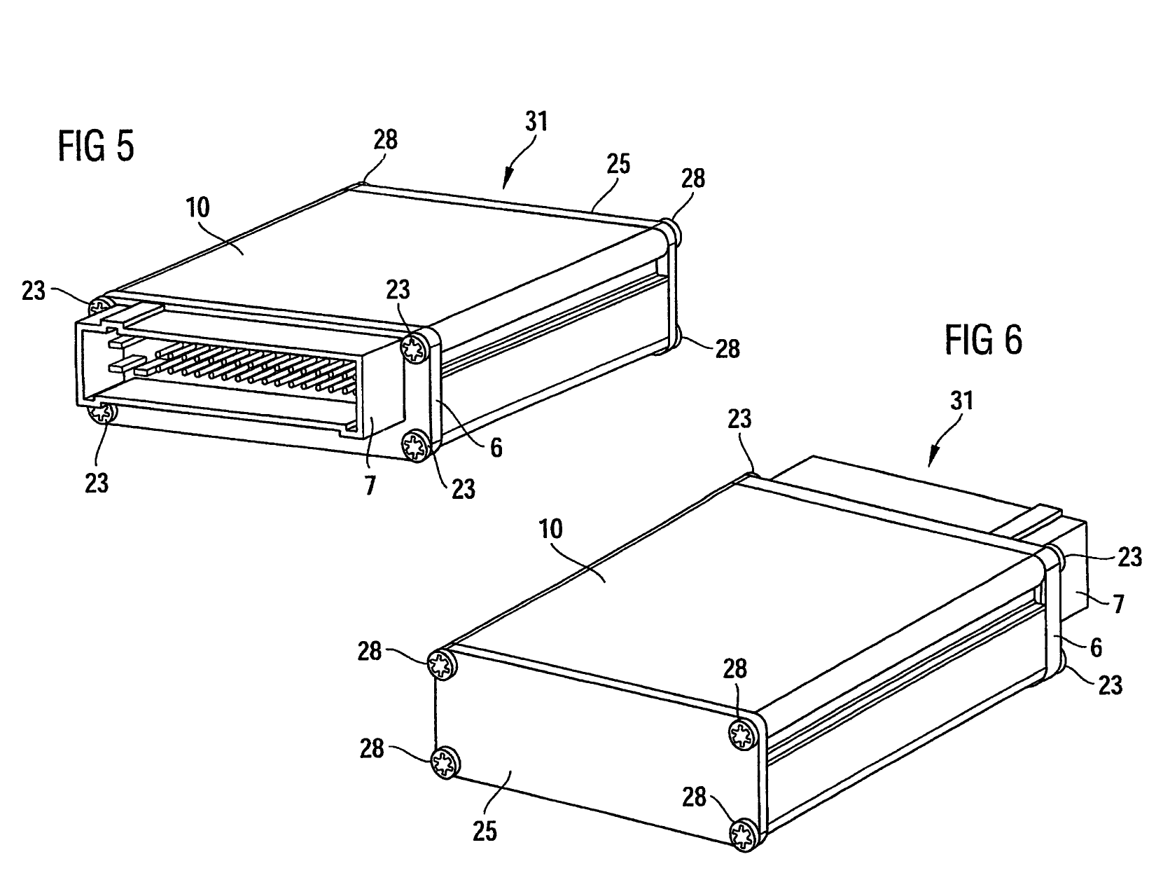

FIG. 5 shows a perspective front view of a fully mounted switching module;

FIG. 6 shows a perspective view of the rear of the switching module from FIG. 5;

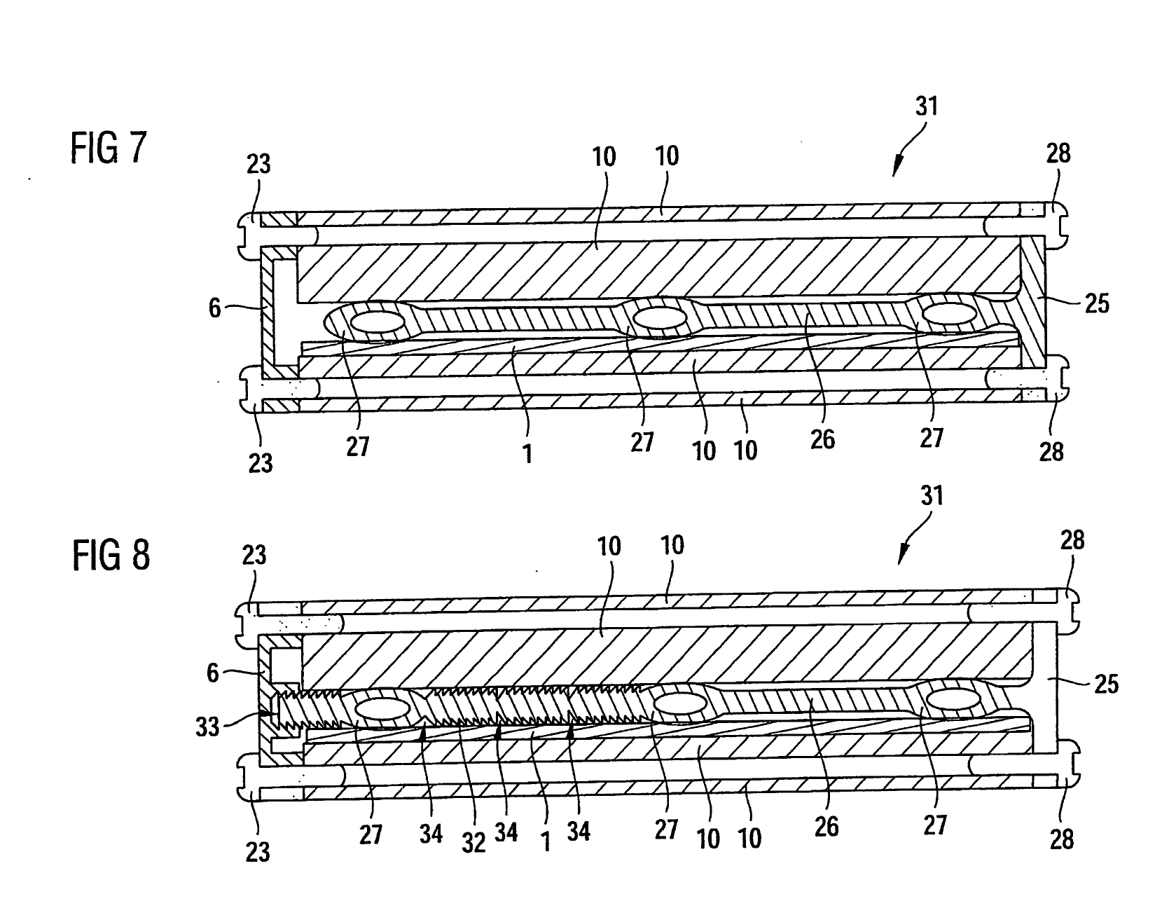

FIG. 7 shows a section through the switching module from FIGS. 5 and 6;

FIG. 8 shows a section through a modified embodiment of a switching module;

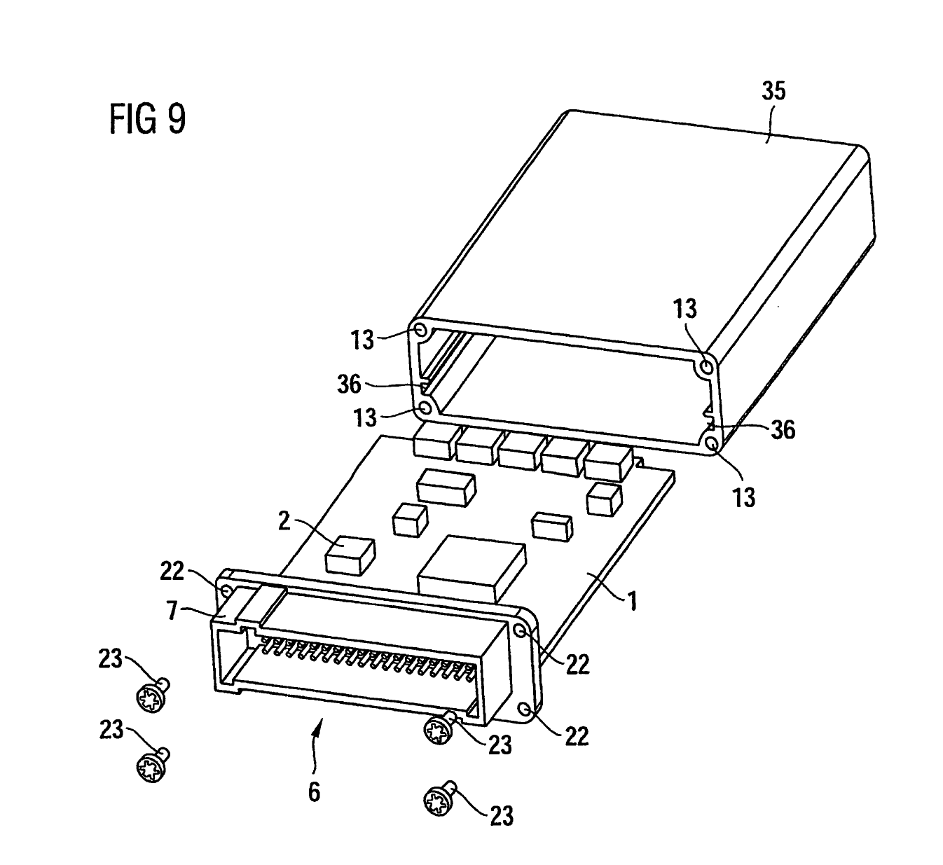

FIG. 9 shows a perspective view of a fixing process, in which a printed circuit board is inserted into a modified hollow element and a cover element is fixed to the hollow element;

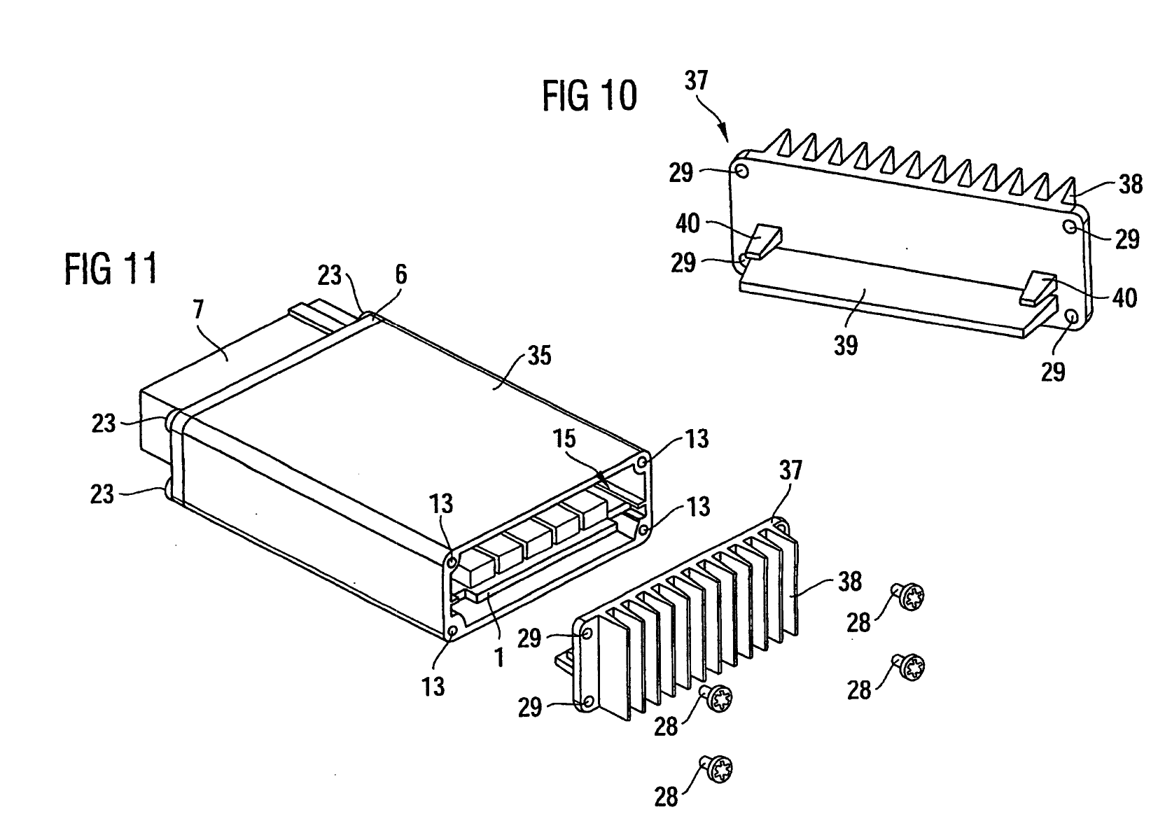

FIG. 10 shows a perspective view of a rear cover element for the hollow element from FIG. 9;

FIG. 11 shows a perspective view, illustrating the attachment of the rear cover element from FIG. 10 to the hollow element;

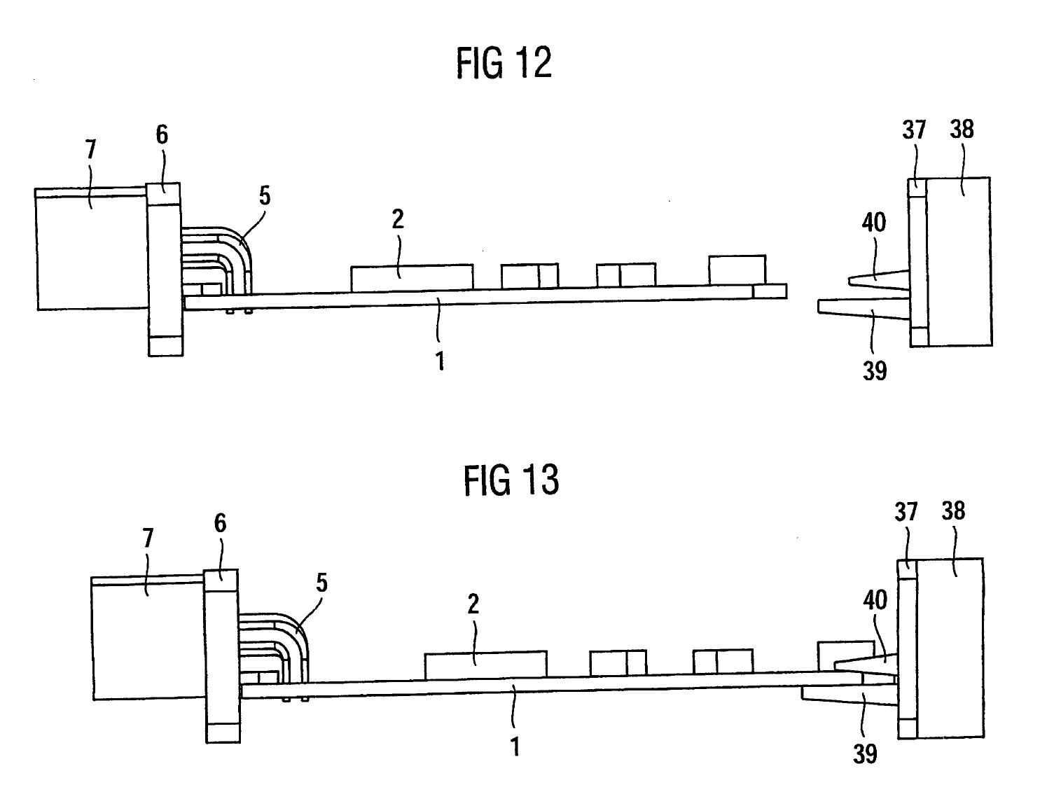

FIG. 12 shows a detailed diagram illustrating the attachment of the rear cover element;

FIG. 13 shows a detailed diagram illustrating the rear cover element attached to the printed circuit board;

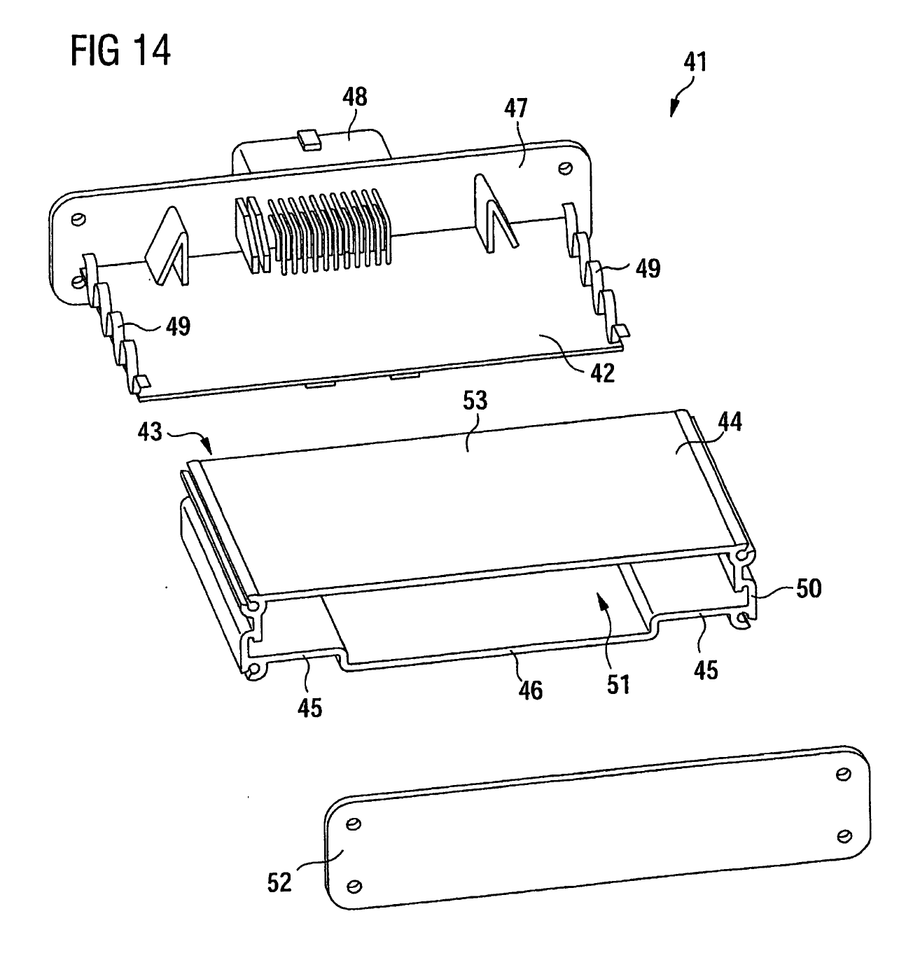

FIG. 14 shows an exploded view of a modified switching module;

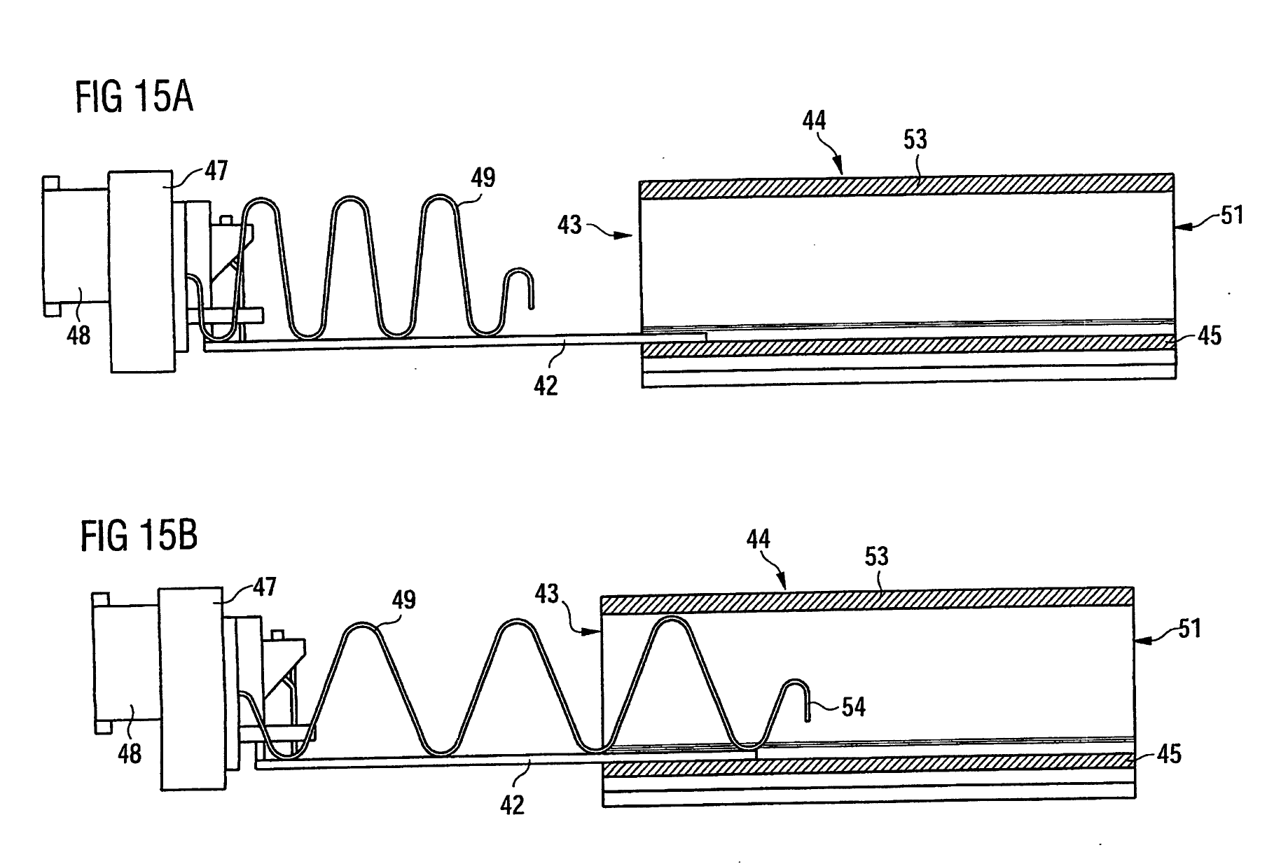

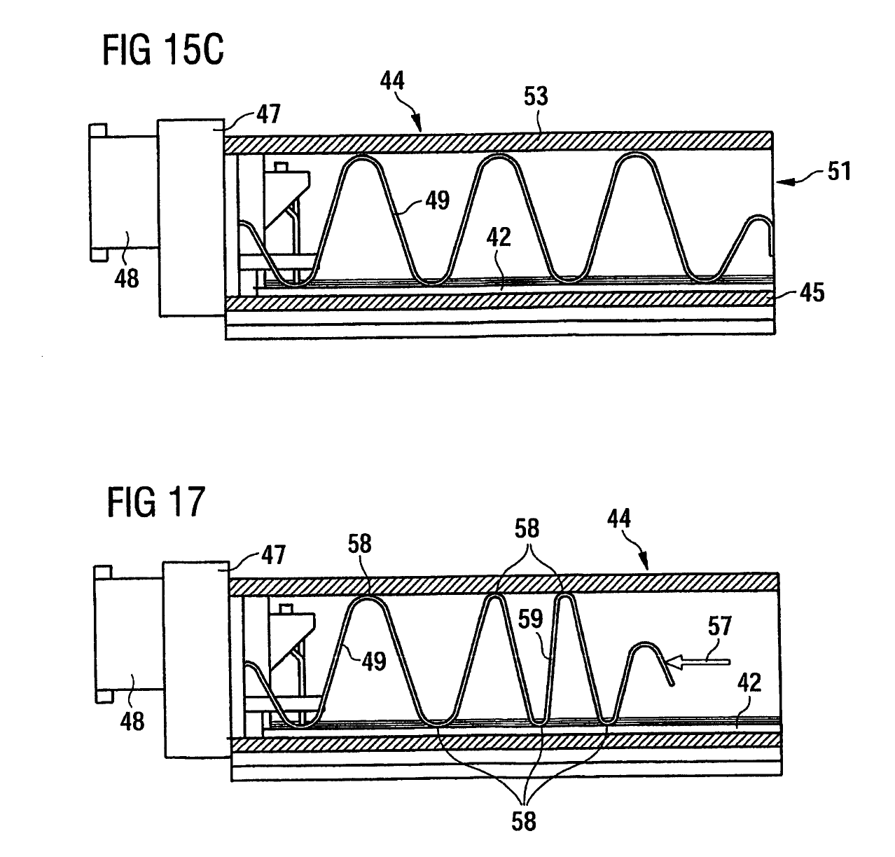

FIGS. 15A to 15C show sections through the switching module from FIG. 14 during insertion of the printed circuit board;

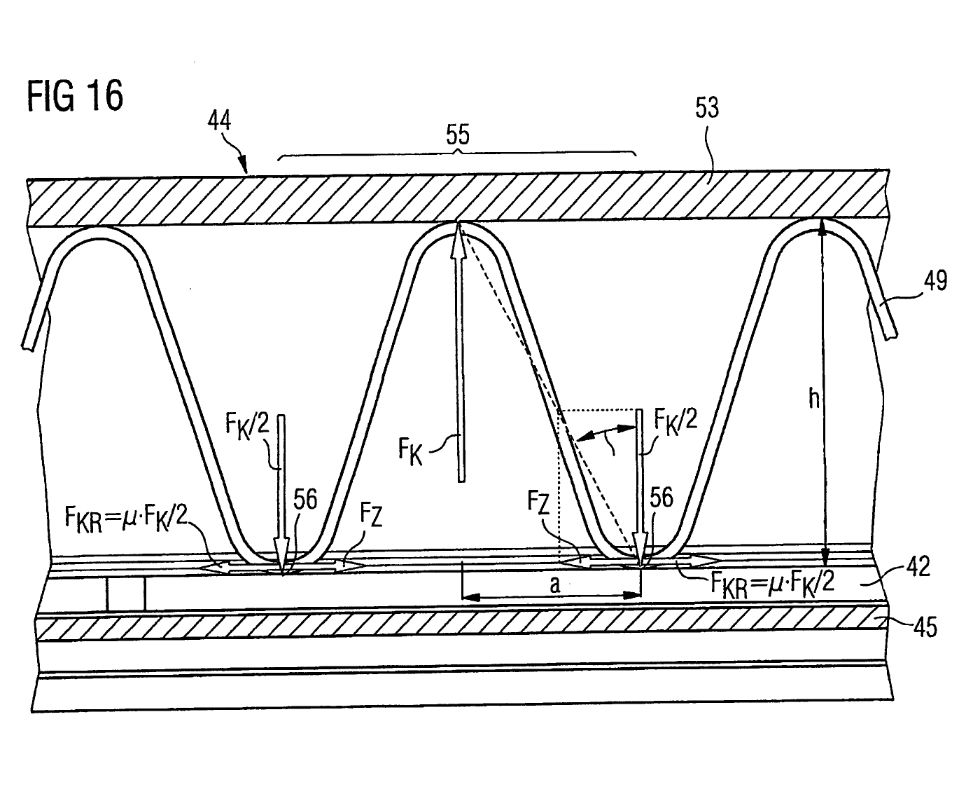

FIG. 16 shows a section through the switching module from FIG. 14, in which the forces acting on a multiple contact strip are marked;

FIG. 17 shows a section through the switching module from FIG. 14 with a seized multiple contact strip;

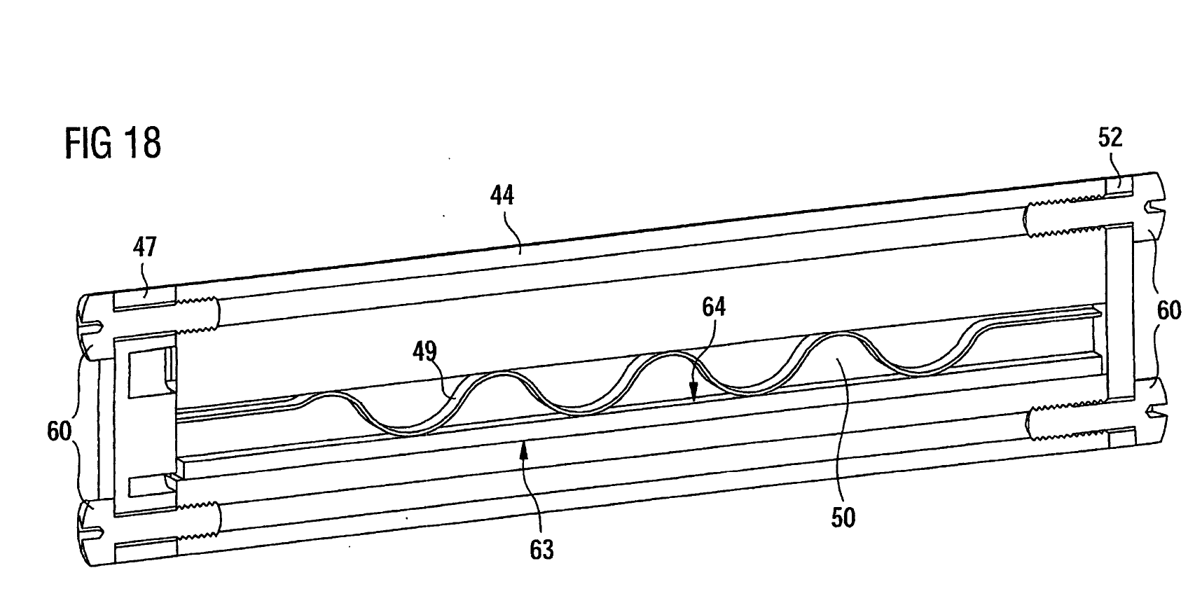

FIG. 18 shows a further section through the switching module from FIGS. 14 to 17;

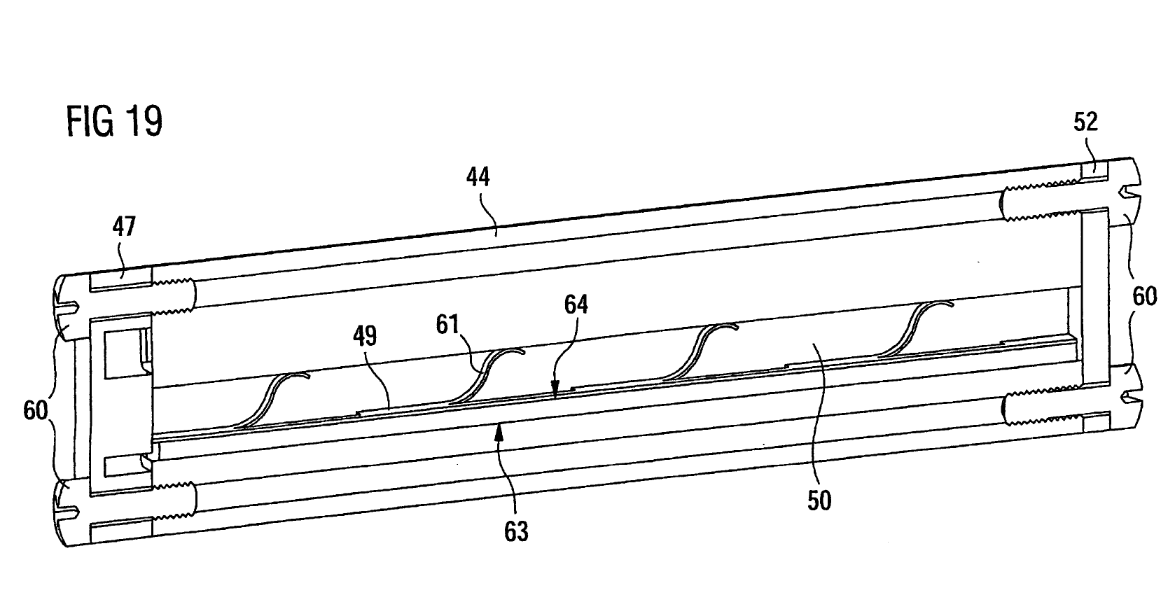

FIG. 19 shows a section through a modified switching module, in which a multiple contact strip with individual spring projections is used;

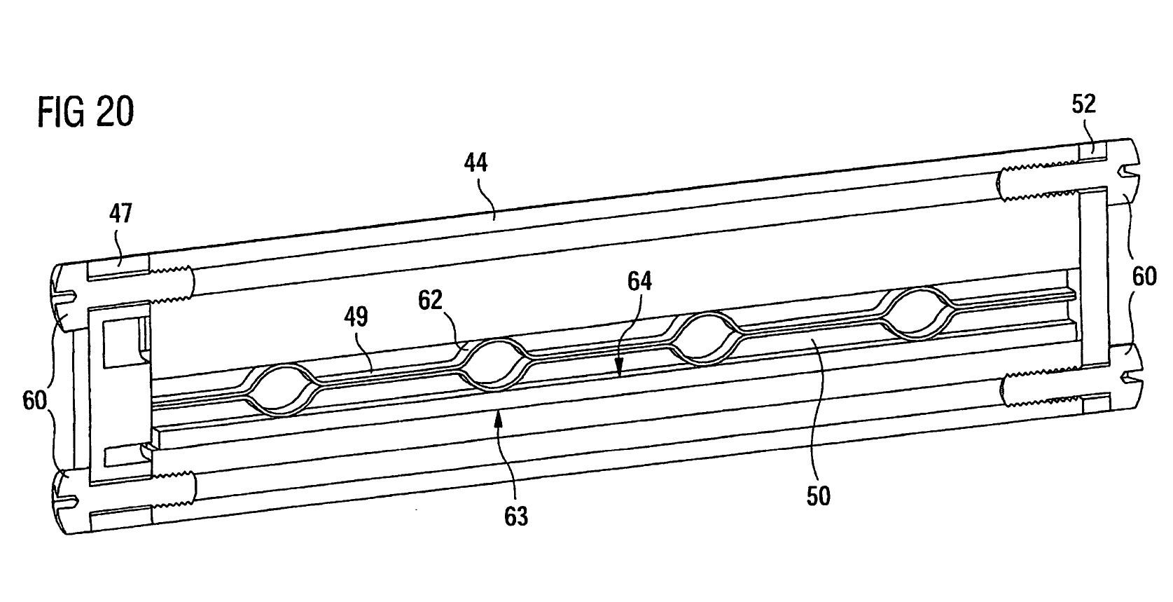

FIG. 20 shows a section through a switching module, in which a multiple contact strip with lock rings is used; and

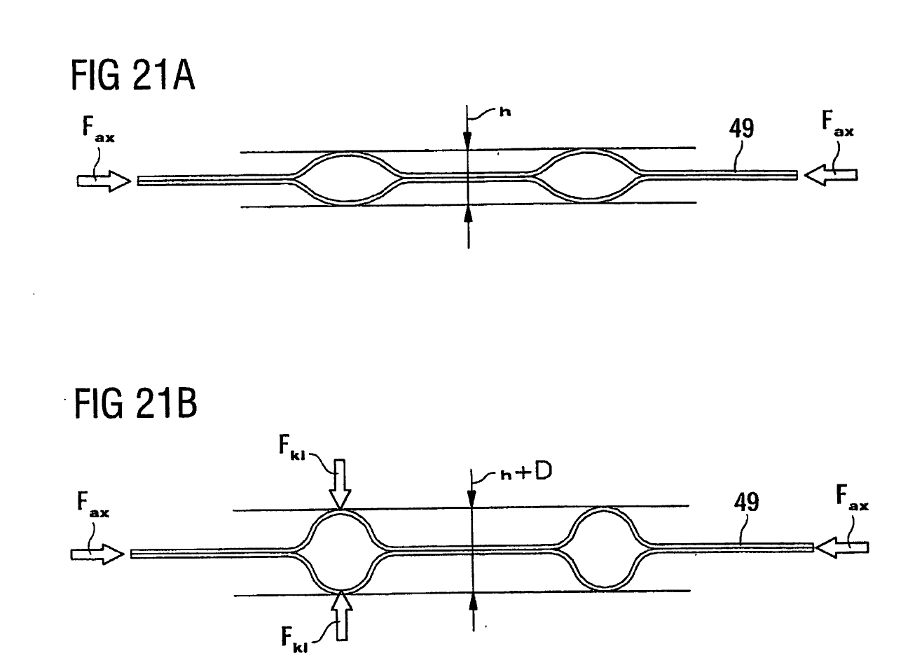

FIGS. 21A and 21B show a diagram of the compression of a multiple contact strip equipped with lock rings.

FIG. 1 shows a printed circuit board 1, which is fitted with electronic components 2. The printed circuit board 1 together with the components 2 is referred to below as electronic components 3. Soldering eyelets 4 for contact pins 5 of a plug connector 7 configured on a cover element 6 are provided in the printed circuit board 1. The cover element 6 provided with the plug connector 7 is referred to below as the front cover element 6.

The printed circuit board 1 thereby has latch holes 8, into which the latching knobs 9 configured on the cover element 6 can latch.

FIG. 2 shows a hollow element 10, which was separated from a hollow profile to correspond to the length of the printed circuit board 1. The hollow profile is therefore the semi-finished product, from which the hollow element 10 can be produced by a simple separation operation. The sectional profile of the hollow element 10 is configured such that the cover element 6 can be attached to a front transverse side 11, to close a front opening 12. To this end recesses 13 are provided along the longitudinal edges of the hollow element 10, into which self-tapping screws for example can be screwed. The recesses 13 extend along the longitudinal edges of the hollow element 10 and the front transverse side 11 to a rear transverse side 14, so that a rear opening 15 on the rear transverse side 14 can also be covered using a suitable cover element.

The sectional profile is also configured such that bearing surfaces 16 are present, on which the inserted printed circuit board 1 rests. With the exemplary embodiment of the hollow element 10 shown in FIG. 2, the bearing surfaces 16 are arranged such that a printed circuit board 1 with components fitted on both sides can also be inserted into the hollow element 10. The height of the hollow element 10 is selected such that the components 2 generally used on the printed circuit board 1 have sufficient space in the hollow element 10.

The bearing surfaces 16 allow a large area of contact between the hollow element 10 and the printed circuit board 1 inserted into the hollow element 10. This large area of contact points allows the heat loss generated by the components 2 on the printed circuit board 1 to be transferred from the printed circuit board 1 to the hollow element 10 and to be dissipated from there to the ambient air.

Encapsulated guide grooves 17 are also provided in the hollow element 10, the function of which is described in more detail below. With the exemplary embodiment shown in FIG. 2 the guide grooves 17 are each made up of an inner guide stud 18 and a lateral outer wall 19. The bearing surfaces 16 are however part of the lower outer wall 20 of the hollow element 10. The upper outer wall 21 is of no specific pattern and runs in a straight line between the recesses 13 arranged along the longitudinal edges.

FIG. 3 shows a perspective view of how the printed circuit board 1 is inserted into the hollow element 10. The printed circuit board 1 is first placed on the bearing surfaces 16 and then inserted below the guide stud 18 through into the hollow element 10. During its insertion the printed circuit board 1 is guided by the bearing surface 16 and the lateral outer walls 19. This type of guidance also ensures that screw holes 22 in the cover element 6 come to rest on the recesses 13 in the hollow element 10. The cover element 6 can then be fixed to the hollow element 10 by means of self-tapping screws 23. A sealing ring 24 can also optionally be inserted between the hollow element 10 and the cover element 6. The sectional profile of the sealing ring 24 corresponds to the sectional profile of the hollow element 10, so that after insertion of the printed circuit board 1 into the hollow element 10, the cover element 6 seals the hollow element 10.

FIG. 4 shows a perspective view of the mounting of a rear cover element 25. The rear cover element 25 is equipped with struts 26, on which lock rings 27 are configured. The external diameter of the lock rings 27 is somewhat larger than the height of the guide grooves 17 minus the thickness of the printed circuit board 1. The struts therefore have to be inserted with force into the guide grooves 17. During the insertion process the screws 23 absorb the shear forces acting on the printed circuit board 1.

In a modified exemplary embodiment the lock rings 27 are replaced by further spring elements. The struts can thus be configured as wave-shaped or have leaf springs, which act transversely. The struts 26 can be made of metal or plastic.

In a preferred embodiment the lock rings or spring elements are made of a material with good heat-conducting properties, in particular a metal, e.g. a copper-beryllium alloy. Heat can thereby be efficiently dissipated via the lock rings or spring elements even from the side of the printed circuit board 1 facing away from the bearing surface 16 to the hollow element 10.

The inner guide studs 18 are provided so that the struts 26 do not yield during insertion and shear off the components 2 arranged on the printed circuit board 1. The lock rings 27 cause the printed circuit board 1 to be pressed firmly against the bearing surfaces 16. This ensures the transfer of heat between the printed circuit board 1 and the hollow element 10. The printed circuit board 1 is also protected against vibration loading.

It should be noted that a heat-conducting paste or heat conducting film can be present between the printed circuit board 1 and the bearing surface 16, to insulate the printed circuit board 1 from the hollow element 10. The printed circuit board 1 can also be insulated from the hollow element 10 by anodizing the hollow element 10. In such instances the printed circuit board 1 can initially be inserted into the hollow element 10 in contact with the guide studs 18 and then in the last phase of insertion it can be placed on the bearing surfaces 16 and pressed firmly into place with the struts 26 of the rear cover element 25, so that the electrical insulation provided by the heat-conducting paste, heat conducting film or the oxide layer is maintained.

After insertion of the rear cover element 25 the rear cover element 25 is fixed to the hollow element 10 by means of self-tapping screws 28. Guidance by way of the struts 26 in the guide grooves 17 ensures appropriate positioning of screw holes 29 in the rear cover element 25 on the recesses 13 of the hollow element 10.

The rear cover element 25 and the struts 26 are preferably produced in a single piece as injection molded parts. In a modified exemplary embodiment the cover element 25 and the struts 26 are separate parts, which are mounted separately. In place of the struts 26 for example multiple contact strips provided as packing, on which the lock rings 27 are configured, can be inserted into the hollow element 10.

A sealing ring 30 can also be inserted between the rear cover element 25 and the hollow element 10. The sealing ring 30 brings about sealed closure of the rear opening 15 by means of the rear cover element 25.

The sealing ring 30 has the same form as the sealing ring 24. It is therefore possible to seal the two openings 12 and 15 with one type of sealing ring.

FIG. 5 shows a perspective view of a fully mounted switching module 31. FIG. 6 shows a perspective view from the rear of the fully mounted switching module 31.

FIG. 7 shows a section through the switching module 31. It can clearly be seen that the lock rings 27 are compressed in the guide groove 17, thereby exerting a spring force on the printed circuit board 1, by means of which the printed circuit board 1 is pressed onto the bearing surface 16.

FIG. 8 shows a section through a modified exemplary embodiment of the switching module 31. With this exemplary embodiment the struts 26 are provided with a saw-tooth profile 32, which engages positively in teeth in a recess 33 in the region of the front cover element 6. This latches the rear cover element 25 and the front cover element 6 against each other. In particular the hollow element 10 is clamped between the front cover element 6 and the rear cover element 25. With the modified exemplary embodiment of the switching module 31 shown in FIG. 8 there is therefore essentially no need for the screws 23 and 28. A rigid and sealed switching module 31 can be produced in this manner with very few joining steps and with no screw-tightening and adhesion processes.

The saw-tooth profile 32, the length of the struts 26 and the latching of the recesses 32 should be dimensioned such that the struts 26 extend into the recesses 23 by a sufficient length. To tailor the length of the struts 26 to the length of the printed circuit boards 1, breaking points 34 are provided along the struts 26, by means of which the length of the struts 26 can be reduced and thereby tailored to the length of the respective hollow element 10 and the respective printed circuit board 1. By reducing their length at the breaking points 34, it is therefore possible to tailor the struts 26 to the respective length of the printed circuit board 1. In a further exemplary embodiment (not shown) of the switching module 31, the hollow element 10 is provided with cooling fins on the outside, which improves the transfer of heat from the hollow element 10 to the ambient air.

The hollow element 10 of the switching module 31 shown in FIGS. 5 and 6 is preferably made of a metal material. The embodiment shown in FIG. 9 however has a hollow element 35, which is made of plastic. Guide grooves 36 are provided inside the hollow element 35, which enclose the printed circuit board 1 during insertion. As the heat generated by the printed circuit board 1 is not to be dissipated via the plastic hollow element 35, no specific bearing surface is provided, to produce a large area of contact between the printed circuit board 1 and the hollow element 35. Rather the function of the guide grooves 36 is restricted to fixing the printed circuit board 1 securely inside the hollow element 35.

Cooling must therefore be achieved in a different fashion. FIG. 10 shows a metal rear cover element 37, the outside of which is provided with cooling fins 38. On its inside the rear cover element 37 has a contact strip 39 and two laterally arranged clamping lugs 40. The rear cover element 37, as shown in FIG. 11, is placed over the rear opening 15 of the hollow element 35 and screwed into position there using screws 28.

FIG. 12 shows a sectional view of the printed circuit board 1 and the rear cover element 37 at a time when the rear cover element 37 is not yet completely pushed onto the printed circuit board 1. In contrast in FIG. 13 the rear cover element 37 is pushed completely onto the printed circuit board 1. A large area of the contact strip 39 is in contact with the underside of the printed circuit board 1 and allows the transfer of heat between the printed circuit board 1 and the rear cover element 37. The wedge-shaped clamping lugs 40 thereby ensure the required contact pressure.

The housing concept described here offers a number of advantages. On the on hand the hollow elements 10 and 35 can be tailored to the different types of printed circuit board 1. Tailoring can be achieved without a tool change, as only the cutting process has to be modified. Generally only one set of tools has to be produced for extrusion of the hollow element 10 or the hollow element 35. The length of the hollow element 10 and 35 can always be selected such that no empty space results inside the finished switching module. A further advantage is the low mounting outlay due to the small number of parts. Mounting is also facilitated in that essentially only joining processes have to be carried out. Despite the simple mounting operation, it is possible to produce rigid, mechanically resistant and hermetically sealed housings. A further advantage is that the waste heat generated on the printed circuit board 1 can be reliably dissipated by way of the housing. Also a high level of vibration resistance results, as a large area of the printed circuit board 1 is held in the hollow elements 10 and 35 from at least three sides.

FIG. 14 shows an exploded view of a further switching module 41, which for example accommodates the circuit of a transmission controller or motor control unit on a printed circuit board 42. The printed circuit board 42 can be inserted into the basic housing element 44 through a front opening 43 in a basic housing element 44. During insertion the printed circuit board 42 rests on collars 45 of a housing base. The basic housing element 44 can for example be a separated part of an extrusion molded profile made of aluminum or plastic.

The printed circuit board 42 is attached before insertion into the basic housing element 44 to a front cover 47, which has a bush 48 on the outside, by means of which electrical contact can be made with the printed circuit board 42. Multiple contact strips 49 are also attached to the cover 47 and are inserted into encapsulated guide grooves 50 in the basic housing element 44 during insertion of the printed circuit board 42 into the basic housing element 44. Insertion of the multiple contact strips 49 is described in greater detail below.

After insertion of the printed circuit board 42 and multiple contact strips 49 into the basic housing element 44, a rear opening 51 in the basic housing element 44 is closed by means of a rear cover 52.

FIGS. 15A to 15C show the insertion of the multiple contact strip 49 in detail. For clarity the multiple contact strip 49 and associated guide groove 50 are shown larger than in FIG. 14. It is however essentially also possible to modify the basic housing element 44 and multiple contact strips 49 shown in FIG. 14 such that the multiple contact strips 49 extend from the printed circuit board 42 to a ceiling 53 of the basic housing element 44.

FIG. 15A shows the printed circuit board 42 already inserted into the basic housing element 44. The multiple contact strip 49 is located still in a released state in front of the front opening 43 of the basic housing element 44.

At the time shown in FIG. 15B the printed circuit board 42 has been inserted further into the basic housing element 44. In FIG. 15B a front end 54 of the multiple contact strip 49 has been held in a tool (not shown) and the multiple contact strip 49 has been extended. The tool used to tension the multiple contact strip 49 is inserted through the rear opening 51 into the basic housing element 44.

It should be noted that a tool inserted through the rear opening 51 is not essential for charging the multiple contact strip 49. It is also possible to fix the end 54 of the multiple contact strip 49 on the printed circuit board 42 before insertion. After insertion of the printed circuit board 42, the end 54 of the multiple contact strip 49 can be released from the printed circuit board 42.

After complete insertion of the printed circuit board 42, the multiple contact strip 49, as shown in FIG. 15C, is released. The multiple contact strip then contracts, until it is contact with both the printed circuit board 42 and the ceiling 53 of the basic housing element 44. The low height of the basic housing element 44 or the guide groove 50 does not allow the multiple contact strip 49 to be released completely.

FIG. 16 shows a schematic diagram of the forces acting on the multiple contact strip 49. The forces acting on the multiple contact strip 49 are explained using the example of a spring segment 55.

Axial release forces F_{z}, which act on vertices 56 of the spring segment 55 on the printed circuit board side, result in a contraction (a−Δa) and an increase in height (h+Δh) of the spring segment 55. This results in a transfer of force from the release force F_{z} to the contact force Fₖ, which is a function of the angle of taper α, defined by the ratio of height h to segment length a. With an angle of taper α=45°, the contact force Fₖ is increased compared to the release force F_{z}.

It should also be noted that the release force F_{z} is reduced by the friction force F_{kR}, the following applying: F_{kR}=μFₖ/2. The friction force F_{kR} increases as the contact force Fₖ increases. At equilibrium between the friction force F_{kR} and the release force F_{z}, no further contact force Fₖ is transmitted to the printed circuit board 42. This is the case at a specific angle of taper α_{R}. This angle of taper can be defined as follows: μ=tan α_{R} follows from Fₖ/2=F_{z}/tan α_{R}=μFₖ/2 tan α_{R}. The maximum achievable contact force Fₖ in the spring segment 55 is therefore limited by the friction coefficients for the contact between the multiple contact strip 49 and the printed circuit board 42.

It should be noted that the additional friction force between the multiple contact strip 49 and the ceiling 53 is not taken into account explicitly. However the friction between the multiple contact strip 49 and the ceiling 53 is taken into account implicitly in the total release force F_{z}, as the extent of this force is also a function of the friction between the multiple contact strip 49 and the ceiling 53.

Releasing the coiled multiple contact strip 49 in the guide groove and standing up the spring leg of the multiple contact strip 49 generate a contact pressure F_{z} on the printed circuit board 42, which presses the printed circuit board 42 firmly onto the collars 45 of the housing base 46. The printed circuit board 42 is thereby fixed mechanically in the basic housing element 44, resulting in good heat conduction between the printed circuit board 42 and the basic housing element 44.

It is essentially possible to use a compression spring in place of the multiple contact strip 49 configured as a tension spring. Such an exemplary embodiment is shown in FIG. 17. With the exemplary embodiment shown in FIG. 17 a pressure 57 is applied from outside. The pressure 57 causes the multiple contact strip 49 to be compressed. Due to irregular friction coefficients at the clamping sites 58, a specific spring slope 59 of the coiled multiple contact strip 49 can be steeper than other spring slopes. In this instance almost all the pressure 57 is absorbed at the clamping sites 58 before the spring slope 59. The pressure 57 is in particular not transmitted to the spring segments further down. For the greater the proportion of pressure 57 absorbed in a spring segment 55, the steeper the spring slopes 59 and the greater the contact pressure acting on the printed circuit board 42 and the ceiling 53, which in turn increases the proportion of pressure 57 absorbed in the respective spring segment 55. This effect can cause irregular contraction of the multiple contact strip 49. This results in locally irregular distribution of the pressure acting on the printed circuit board 42.

If however the multiple contact strip 49 is configured as a tension spring, this risk does not exist. If a clamping site with a potential increase in friction force is present, the spring segments further down will want to contract further and eliminate the spring slope 59 of the spring segment 55 with the potential for seizing as a result of said increase in friction, thereby reducing the steepness of the spring slope 59. This reduces the contact force acting on the printed circuit board 42 and the ceiling 53. The reduction in contact force then reduces the friction force between the multiple contact strip 49 and the printed circuit board 42 and the basic housing element 44. The release force acting in the spring segments 55 away from the seized spring segment 55 therefore tightens the seized spring segment 55, as a result of which the entire spring connection 49 is shortened in a regular manner. This compensatory effect operates at every contact site between the multiple contact strip 49 and the printed circuit board 42 and the basic housing element 44 and ensures regular distribution of the contact force acting on the printed circuit board 42.

A further advantage of a multiple contact strip 49 configured as a tension spring is that the pressure 57 does not always have to be applied from outside to hold the printed circuit board 42 down. The axial spring force required to hold the printed circuit board 42 down is generated and independently maintained by a multiple contact strip 49 configured as a tension spring itself, without an outside force being required to act on the multiple contact strip 49. This significantly facilitates mounting, as with a multiple contact strip 49 configured as a tension spring the cover 52 can simply be screwed onto the rear opening 51, without the multiple contact strip 49 having to be compressed.

FIG. 18 shows a section through the switching module 41 in the fully mounted state, with the option of the multiple contact strip 49 being a tension spring or a compression spring. Irrespective of this with the embodiment shown the covers 47 and 52 are fixed to the basic housing element with screws 60. If the multiple contact strip 49 is a compression spring, the pressure required to compress the compression spring is applied by the covers 47 and 52.

FIG. 19 shows a further embodiment of the switching module 41, in which the multiple contact strip 49 has individual spring projections 61. This embodiment is particularly advantageous, when the multiple contact strip 49 for example is to be latched in the printed circuit board 42. It is also advantageous, if the flat side of the multiple contact strip 49 opposite the spring projections 61 rests on the printed circuit board 42, as this can then be evenly loaded. Also such multiple contact strips 49 are particularly simple to manufacture.

FIG. 20 finally shows a further exemplary embodiment, in which the multiple contact strip 49 has lock rings 62. The multiple contact strip 49 shown in the exemplary embodiment in FIG. 20 can be considered to be made up of two coiled multiple contact strips. The multiple contact strip 49 of the exemplary embodiment shown in FIG. 20 can also be configured as a tension spring or a compression spring, in the same way as the multiple contact strips 49 shown in FIGS. 14 to 18. FIGS. 21A and 21B show the function of the multiple contact strip 49 from FIG. 20. The action of a compression force Fₐₓ causes the lock rings 62 to be deformed to form upright ellipses, so that the lock rings 62 exert a contact force Fₖ₁ on the printed circuit board 42 and the basic housing element 44.

The advantage of these embodiments is that the multiple contact strips 49 of the exemplary embodiments shown in FIGS. 19 and 20 can be subjected to high pressure more readily than the coiled multiple contact strips 49 of the exemplary embodiments shown in FIGS. 14 to 18. There is therefore less risk with the exemplary embodiments shown in FIGS. 19 and 20 of the multiple contact strip 49 seizing during insertion, as is the case with the coiled multiple contact strip 49.

It should be noted that further modified embodiments of multiple contact strips can be used. For example a multiple contact strip with a single spring segment 55 can also be used to hold down the printed circuit board 42.

A further possible embodiment comprises a multiple contact strip, in which a plurality of lock rings 62 arranged one on top of the other provide the contact force required to hold the printed circuit board 42 down. Such a multiple contact strip can be seen as a stack of coiled multiple contact strips arranged one on top of the other, together forming a spring net.

The exemplary embodiments shown in FIGS. 19 to 21 share the fact that the printed circuit board 42 is inserted into the basic housing element 44 such that a flat side 63 of the housing base 46 and a flat side 64 of the ceiling 53 face each other. This has the advantage that the multiple contact strip 49 can be inserted into the basic housing element 44 together with the printed circuit board 42. To this end the multiple contact strip 49 can also be attached to one of the covers 47 and 52.

With the exemplary embodiments shown in FIGS. 14 to 21, the printed circuit board 42 is essentially fixed by the spring force of the multiple contact strip 49 and by the covers 47 and 52. With a printed circuit board, which has a smaller surface than an assigned basic housing element, knobs or pins can be provided for example in the region of the guide grooves to fix the printed circuit board in the direction of insertion.

It is also possible to provide one or more multiple contact strips in a central region of the printed circuit board in addition to the multiple contact strips arranged at the edges of the printed circuit board. In this instance it is expedient to brace the printed circuit board at points of contact with the multiple contact strip, in order to prevent the printed circuit board breaking.

With a further modified embodiment transverse strips are attached to the printed circuit boards in the nature of a component and multiple contact strips extending longitudinally are attached thereto. In this instance the multiple contact strips do not have to be attached to the covers used to close the basic housing element.

Finally it is also possible to insert longitudinal strips between the printed circuit board and the basic housing element, to which one or more multiple contact strips extending transversely are attached.

Finally it should be noted that the switching module does not necessarily have to accommodate a printed circuit board. It is also possible to insert a single component, for example a relay or a transformer, in the basic housing element. In this instance there is no need for the encapsulated guide grooves, as there is no risk of the element being damaged by the multiple contact strips during insertion.

1-23. (canceled)

24. A method for mounting a switching module, which comprises:
providing a circuit support with flat sides, a basic housing element with walls and an interior formed with guide devices, and cover element for closing the basic housing element;
inserting the circuit support into the basic housing element with the flat sides facing towards the walls of the basic housing element;
inserting a longitudinally extended pressure strip between the circuit support and the basic housing element, bracing the pressure strip with a given compression force against a flat side of the circuit support, and guiding the pressure strip with the guide devices in the interior of the basic housing element; and
closing the basic housing element with the cover elements.

25. The method according to claim 24, wherein the pressure strip is a tension spring, and the method comprises inserting the circuit support in a tensed state of the spring and subsequently releasing the spring to fix the circuit support in the basic housing element.

26. The method according to claim 24, wherein the pressure strip is a compression spring and the method comprises fixing the circuit support by subjecting the spring to a compression pressure.

27. The method according to claim 26, which comprises applying the compression pressure by way of the cover elements of the basic housing element.

28. The method according to claim 24, which comprises guiding the pressure strip inside the basic housing element by an encapsulated guide groove.

29. The method according to claim 24, which comprises guiding the circuit support by guide elements during insertion into the basic housing element.

30. The method according to claim 29, which comprises fitting the circuit support with components on both sides before insertion into the basic housing element.

31. The method according to claim 24, which comprises fixing a cover element to the circuit support before insertion of the circuit support into the basic housing element.

32. The method according to claim 31, which comprises connecting contact means configured on the cover element to the circuit support before insertion of the circuit support into the basic housing element.

33. The method according to claim 24, which comprises inserting the pressure strip into the basic housing element together with the circuit support.

34. The method according to claim 24, providing a cover element with the pressure strip attached to an opening in the basic housing element.

35. The method according to claim 24, which comprises adapting the pressure strip to a length of the basic housing element by breaking at predetermined breaking points before insertion into the basic housing element.

36. The method according to claim 24, which comprises holding the pressure strip in a form lock in a recess in an opposite cover element.

37. The method according to claim 36, wherein the pressure strip is configured with a saw-tooth profile and the pressure strip is held positively in latch points on the recess.

38. The method according to claim 36, which comprises clamping the basic housing element between mutually opposite cover elements.

39. The method according to claim 24, which comprises fixing a cover element to the circuit support by way of clamping devices during an attachment of the cover element to an opening in the basic housing element.

40. The method according to claim 24, which comprises sealing openings formed on mutually opposite sides of the basic housing element by way of mutually identical seals.

41. A switching module with an electronic component disposed inside a housing, wherein the switching module is produced with the method according to claim 24.
